(19) United States
(12) Patent Application Publication
(10) Pub. No.: US 2025/0003692 A1
(43) Pub. Date: Jan. 2, 2025

(54) HEAT EXCHANGER APPARATUS AND A HEAT MANAGEMENT SYSTEM USING THE SAME

(71) Applicants: HYUNDAI MOTOR COMPANY, Seoul (KR); KIA CORPORATION, Seoul (KR)

(72) Inventors: Hyeon Keun Yun, Hwaseong-si (KR); Jong Min Lee, Daegu (KR); Hyo Chan Bae, Hwaseong-si (KR); Dae Kyu Han, Seoul (KR)

(73) Assignees: HYUNDAI MOTOR COMPANY, Seoul (KR); KIA CORPORATION, Seoul (KR)

(21) Appl. No.: 18/509,031

(22) Filed: Nov. 14, 2023

(30) Foreign Application Priority Data
Jun. 28, 2023 (KR) 10-2023-0083718

(51) Int. Cl. F28D 9/00; H01M 10/613

(52) U.S. Cl. CPC F28D 9/0056; H01M 10/613

(57) ABSTRACT

A heat exchanger apparatus and a heat management system facilitate temperature management of each cooling medium through heat exchange between a refrigerant and a coolant and diversify the flow direction of the coolant by providing a bypass circulation path through which the coolant bypasses the heat exchange with the refrigerant in addition to the circulation path through which the coolant exchanges heat with the refrigerant. As a result, a manifold for a bypass path may be eliminated through which the coolant bypasses the heat exchanger, reducing the number of components, material costs, weight, and the package size of the cooling circuit.

### CROSS REFERENCE TO RELATED APPLICATION

The present application claims priority to Korean Patent Application No. 10-2023-0083718, filed Jun. 28, 2023, the entire content of which is incorporated herein for all purposes by this reference.

### BACKGROUND

### Technical Field

The present disclosure relates to a heat exchanger apparatus and a heat management system using the same that are capable of facilitating temperature management of a cooling medium and simplifying the cooling circuit by diversifying the cooling medium circulation direction.

### Description of the Related Art

In general, a heat exchanger is a device that performs heat exchange by absorbing or dissipating heat between different heat transfer media. Heat exchangers include condensers and evaporators that use refrigerants as the heat transfer medium, radiators and heater cores that use coolant, and oil coolers that utilize oil from engines and transmissions as the heat exchange medium. Such heat exchangers are designed and manufactured in a variety of types and configurations to meet specific needs of different applications.

Heat exchangers operate by circulating coolant through coolant plates and refrigerant through refrigerant plates, allowing refrigerant and coolant to exchange heat through the refrigerant and coolant plates.

However, heat exchangers are typically designed to allow coolant or refrigerant to circulate in and out. As a result, heat exchangers perform heat exchange between coolant and refrigerant even when it is unnecessary, leading to a decrease in temperature management efficiency.

Additionally, heat exchangers need to have a manifold to distribute coolant selectively, which requires a joint structure that causes the overall package of the cooling circuit to become larger.

The foregoing is intended merely to aid in understanding the background of the present disclosure. The foregoing is not intended to mean that the present disclosure falls within the purview of the related art that is already known to those of ordinary skill in the art.

### SUMMARY

The present disclosure aims to provide a heat exchanger apparatus and a heat management system using the same that are capable of facilitating temperature management of the cooling medium and simplifying the cooling circuit by diversifying the cooling medium circulation direction.

In order to accomplish the above object, a heat exchanger apparatus according to the present disclosure includes: a heat exchanger having a plurality of stacked heat exchange plates equipped with a guide member forming a flow path for the flow of refrigerant or coolant; a refrigerant inlet and a refrigerant outlet connected to the heat exchanger to allow the refrigerant to flow and circulate through some of the plurality of heat exchange plates; and a plurality of circulation ports connected to the heat exchanger to allow the coolant to flow and circulate through some of the plurality of heat exchange plates. Some of the plurality of circulation ports are installed to face each other in the heat exchanger to form a bypass path.

In one example, the heat exchanger includes a heat exchange plate for the refrigerant and a heat exchange plate for the coolant. The heat exchange plate for the refrigerant is communicably connected with the refrigerant inlet and the refrigerant outlet. The heat exchange plate for the coolant is communicably connected with the plurality of circulation ports.

In one example, the refrigerant inlet and refrigerant outlet are positioned on both sides of the guide member. Some circulation ports are positioned on both sides of the guide member on the opposite side of the refrigerant inlet and refrigerant outlet.

In one example, the plurality of circulation ports includes a first circulation port, a second circulation port, and a third circulation port. The first and second circulation ports are installed on one side of the heat exchanger. The third circulation port is installed on the opposite side of the heat exchanger in a direction facing the first circulation port or the second circulation port.

In one example, the plurality of circulation ports includes a first circulation port, a second circulation port, a third circulation port, and a fourth circulation port. The first and second circulation ports are installed on one side of the heat exchanger. The third circulation port is installed on the opposite side of the heat exchanger in a direction facing the first circulation port. The fourth circulation port is installed on the opposite side of the heat exchanger in a direction facing the second circulation port.

A heat management system according to the present disclosure includes a multi-valve that circulates refrigerant selectively through a plurality of heat management components in a cooling medium circulation line. The system also includes a heat exchanger apparatus connected to the multi-valve and other heat management components in the cooling medium circulation line to adjust the temperature of the cooling medium. The heat exchanger apparatus includes heat exchange plates for heat exchange between the cooling medium and heat exchange medium. The heat exchanger apparatus further includes a plurality of circulation ports for circulation of the cooling medium. Some of the circulation ports are arranged in a direction facing each other to form a bypass path in the heat exchanger apparatus.

In one example, the heat management components include a battery, a radiator, and power electronics (PE). The heat exchanger apparatus includes a first circulation path connected to the multi-valve, a second circulation path connected to the radiator or PE, and a third circulation path connected to the battery or multi-valve.

In one example, the heat exchanger apparatus is configured to have the bypass path formed by the second and third circulation paths.

In one example, the multi-valve is configured to close the first circulation path when cooling the battery or PE using the radiator to form a circulation flow allowing the cooling medium to enter the heat exchanger apparatus through the third circulation path and be discharged through the second circulation path.

In one example, the multi-valve is configured to circulate the cooling medium passed through the battery to the radiator through the PE and heat exchanger apparatus when cooling the battery or PE using the radiator.

In one example, the multiple-valve is configured to open the first circulation path when cooling the battery using the heat exchanger apparatus to form a circulation flow allowing the cooling medium passed through the third circulation path of the heat exchanger apparatus to be discharged through the first circulation path.

In one example, the multi-valve is configured to circulate the cooling medium passed through the battery to the heat exchanger apparatus when cooling the battery using the heat exchanger apparatus.

In one example, the multi-value is configured to open the first circulation path when implementing heat pump functionality using the heat exchanger apparatus to form a circulation flow allowing the cooling medium passed through the second circulation path of the heat exchanger apparatus to be discharged through the first circulation path.

In one example, the multi-valve is configured to circulate the cooling medium passed through the PE to the heat exchanger apparatus when implementing the heat pump functionality using the heat exchanger apparatus.

The heat exchanger apparatus and the heat management system structured as described above are advantageous in terms of facilitating temperature management of each cooling medium through heat exchange between the refrigerant and the coolant. The apparatus and system do so while diversifying the flow direction of the coolant by providing a bypass circulation path through which the coolant bypasses the heat exchange with the refrigerant in addition to the circulation path through which the coolant exchanges heat with the refrigerant. As a result, the elimination of the manifold for the bypass path through which the coolant bypasses the heat exchanger reduces the number of components, material costs, weight, and package size of the cooling circuit.

### BRIEF DESCRIPTION OF THE DRAWINGS

In order that the disclosure may be well understood, various forms thereof are described herein, given by way of example, reference being made to the accompanying drawings, in which:

FIG. 1 is a diagram illustrating a heat exchanger apparatus according to an embodiment of the present disclosure;

FIG. 2 is an exploded view of the heat exchanger apparatus of FIG. 1;

FIG. 3 is a diagram illustrating the circulation of refrigerant in the heat exchanger apparatus of FIG. 1;

FIG. 4 is a diagram illustrating the circulation of coolant in the heat exchanger apparatus of FIG. 1;

FIG. 5 is a diagram illustrating a heat exchanger apparatus according to another embodiment of the present disclosure;

FIG. 6 is a diagram illustrating a heat management system according to an embodiment of the present disclosure;

FIG. 7 is a diagram illustrating a mechanism of cooling a battery and power electronics (PE) using a radiator in the heat management system of FIG. 6;

FIG. 8 is a diagram illustrating a mechanism of cooling a battery, PE, and a radiator using a heat exchanger apparatus in the heat management system of FIG. 6; and

FIG. 9 is a diagram illustrating a mechanism of heating a heat pump and battery using a heat exchanger apparatus in the heat management system of FIG. 6.

### DETAILED DESCRIPTION

Hereinafter, descriptions of the disclosed embodiments are provided in the present specification with reference to the accompanying drawings in which the same reference numbers are assigned to refer to the same or like components. Redundant descriptions thereof have been omitted.

As used in the following description, the suffixes “module” and “unit” are granted or used interchangeably in consideration of ease of description but, by themselves, have no distinct meaning or role.

In addition, detailed descriptions of well-known technologies related to the disclosed embodiments in the present specification may have been omitted to avoid obscuring the subject matter of the disclosed embodiments in the present specification. In addition, the accompanying drawings are only to aid in understanding the disclosed embodiments in the present specification. The accompanying drawings do not limit the technical spirit disclosed herein. It should be understood that the described embodiments include all changes, equivalents, and substitutes within the spirit and scope of the disclosure.

As used herein, terms including an ordinal number such as “first” and “second” can be used to describe various components without limiting the components. The terms are used only for distinguishing one component from another component.

It should be understood that, when a component is referred to as being “connected to” or “coupled to” another component, the component can be directly connected or coupled to the other component, or an intervening component may be present. In contrast, when a component is referred to as being “directly connected to” or “directly coupled to” another component, there are no intervening components present.

As used herein, the singular forms are intended to include the plural forms as well, unless the context clearly indicates otherwise. When a component, device, element, or the like of the present disclosure is described as having a purpose or performing an operation, function, or the like, the component, device, or element should be considered herein as being “configured to” meet that purpose or to perform that operation or function.

It should be further understood that the terms “comprises,” “includes,” or “has,” and variations thereof, when used in this specification, specify the presence of a stated feature, number, step, operation, component, element, or a combination thereof. Such terms do not preclude the presence or addition of one or more other features, numbers, steps, operations, components, elements, or combinations thereof.

For example, each controller may include a communication device communicating with another controller or sensor to control a function in charge, a memory (such as or including a non-transitory memory) that stores operating system or logic instructions and input/output information, and one or more processors for determination, operation, and decision-making necessary for functions in charge.

Hereinafter, descriptions are made of the heat exchanger apparatus and heat management system using the same according to embodiments of the present disclosure with reference to accompanying drawings.

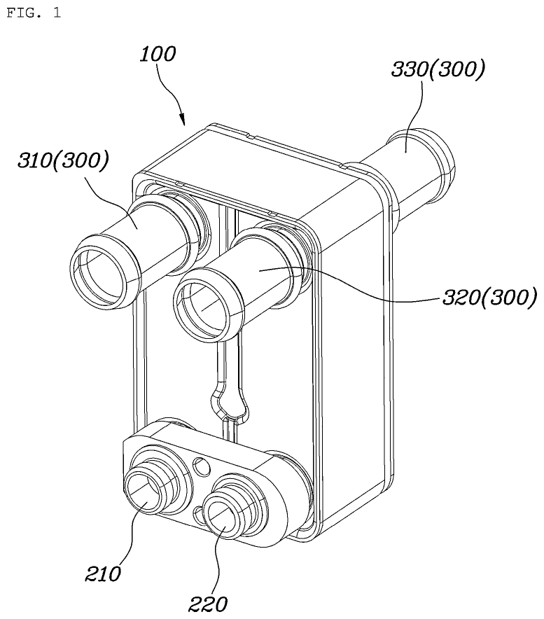

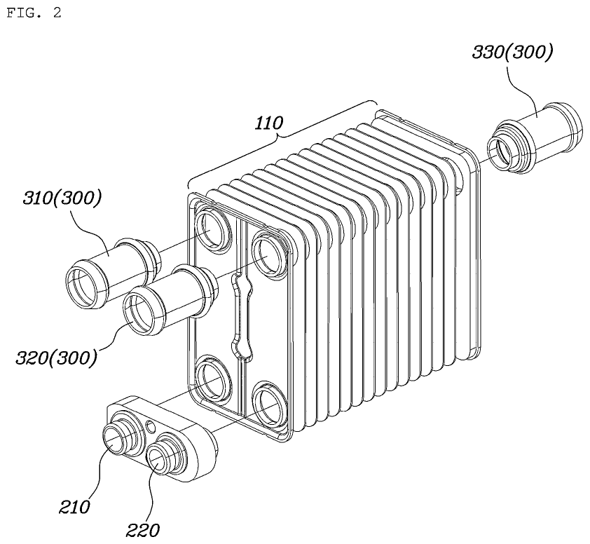

As shown in FIGS. 1 and 2, the heat exchanger apparatus according to the present disclosure includes a heat exchanger 100 formed by stacking a plurality of heat exchange plates 110 equipped with guide members 111 to form flow paths for circulating refrigerant or coolant. The apparatus also includes a refrigerant inlet 210 and a refrigerant outlet 220 allowing for refrigerant flow and connected to the heat exchanger 100 to enable the circulation of refrigerant through some of the heat exchange plates 110. The apparatus also includes a plurality of circulation ports 300 allowing for coolant flow and connected to the heat exchanger 100 to facilitate the circulation of coolant through some of the heat exchange plates 110 for cooling purposes.

The heat exchanger 100 includes heat exchange plates for refrigerant and heat exchange plates for coolant. The heat exchange plates for refrigerant are connected with a refrigerant inlet 210 and a refrigerant outlet 220 to allow for refrigerant circulation. The heat exchange plates for coolant are connected with a plurality of circulation ports 300 to facilitate coolant circulation. The heat exchange plates for refrigerant and coolant may be stacked alternately. Each of the heat exchange plates 110 may be configured with a dimple or pin structure to enhance heat transfer efficiency, facilitating temperature management through heat exchange between refrigerant and coolant.

Additionally, a guide member 111 is formed on each heat exchange plate 110 to create flow paths for the circulation of refrigerant or coolant.

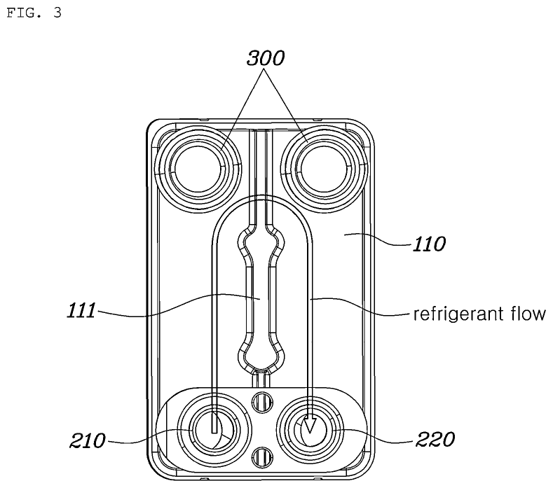

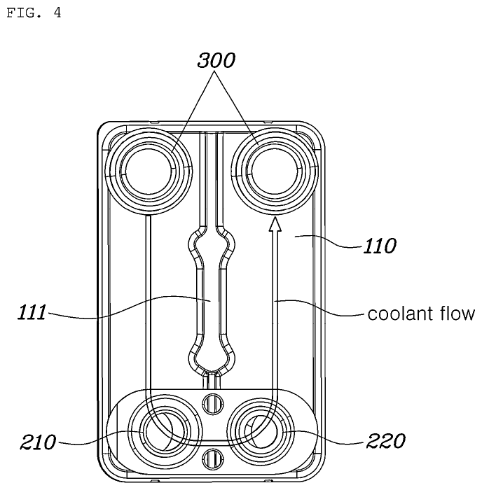

As shown in FIGS. 3 and 4, the guide member 111 is formed to extend a certain length on each heat exchange plate 110. In other words, the guide member 111 on the heat exchange plate 110 for refrigerant is extended a predetermined length from the position where the refrigerant inlet 210 and refrigerant outlet 220 are provided. This forms a bypass path from the refrigerant inlet 210 to the refrigerant outlet 220 allowing for the circulation of refrigerant across the entire surface of the heat exchange plate 110 for refrigerant. Similarly, the guide member 111 on the heat exchange plate 110 for coolant is extended a certain length between different circulation ports 300. This forms a bypass path from one circulation port 300 to another circulation port 300 allowing for the circulation of coolant across the entire surface of the heat exchange plates 110 for coolant.

The refrigerant inlet 210 and refrigerant outlet 220 are positioned on both sides of the guide member 111. Some circulation ports 300 may be positioned on both sides of the guide members 111 on the opposite side of the refrigerant inlet 210 and refrigerant outlet 220. This configuration allows for the avoidance of interference between the refrigerant inlet 210, refrigerant outlet 220, and each circulation port 300 in the heat exchanger 100. This configuration may also improve the heat exchange efficiency between the refrigerant and coolant by forming a crossed flow direction between the circulation flow of refrigerant and coolant.

In particular, the present disclosure includes the installation of some of the circulation ports 300 facing each other in the heat exchanger 100, creating a bypass path.

In other words, in the heat exchanger 100, a plurality of circulation ports 300 are provided for the circulation of coolant. These circulation ports 300 are laterally arranged separately from each other on the heat exchange plates 110 allowing the coolant to circulate along the surface of the heat exchange plates 110. Some circulation ports 300 may be installed to face each other in the heat exchanger 100, forming flow paths that pass through the heat exchange plates 110 in a straight line.

As a result, each circulation port 300 may function as an inlet or outlet depending on the circulation of coolant.

This allows for the coolant to circulate and exchange heat within the heat exchanger 100 or to bypass with minimal resistance, depending on the circulation port 300 through which the coolant flows among the plurality of circulation ports 300.

In an embodiment of the present disclosure, as shown in FIG. 1, the plurality of circulation ports 300 may be composed of a first circulation port 310, a second circulation port 320, and a third circulation port 330. The first and second circulation ports 310 and 320 may be installed on one side of the heat exchanger 100, while the third circulation port 330 may be installed on the opposite side of the heat exchanger 100 in a direction facing either the first circulation port 310 or the second circulation port 320 to establish communication therebetween.

This configuration allows the plurality of circulation ports 300 to form paths for the inlet and outlet of the coolant and, depending on the selective circulation of the coolant, determine the flow direction within the heat exchanger 100.

For example, four different coolant circulation directions may be implemented. These directions may include: the flow of coolant entering the first circulation port 310 and exiting from the second circulation port 320; the flow of coolant entering the second circulation port 320 and exiting from the first circulation port 310; the flow of coolant entering the first circulation port 310 and exiting from the third circulation port 330; and the flow of coolant entering the third circulation port 330 and exiting from the first circulation port 310. These coolant circulation flows enable the coolant to exchange heat with the refrigerant as it circulates within the heat exchanger 100.

When the flow direction involves the coolant entering the second circulation port 320 and exiting from the third circulation port 330, or involves the coolant entering the third circulation port 330 and exiting from the second circulation port 320, the second circulation port 320 and the third circulation port 330 may be installed facing each other, creating a bypass path. This allows for the formation of a bypass flow path for the coolant to pass through the heat exchanger 100 with minimal resistance.

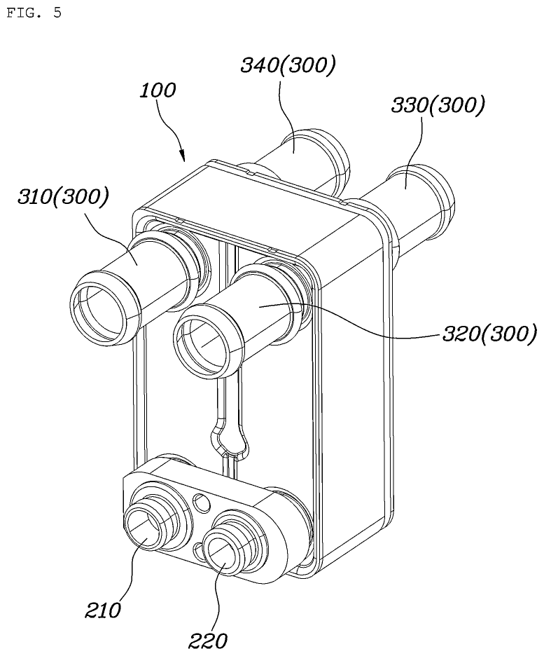

In another embodiment, as shown in FIG. 5, the plurality of circulation ports 300 may be composed of a first circulation port 310, a second circulation port 320, a third circulation port 330, and a fourth circulation port 340. The first and second circulation ports 310 and 320 are installed on one side of the heat exchanger 100. The third circulation port 330 is installed on the opposite side of the heat exchanger 100 in a direction facing the first circulation port 310. The fourth circulation port 340 may be installed on the opposite side of the heat exchanger 100 in a direction facing the second circulation port 320.

This configuration allows the plurality of circulation ports 300 to form paths for the inlet and outlet of the coolant and, depending on the selective circulation of the coolant, the flow direction within the heat exchanger 100 may be determined.

For example, eight different coolant circulation directions may be implemented. These directions may include: the flow of coolant entering the first circulation port 310 and exiting from the second circulation port 320; the flow of coolant entering the second circulation port 320 and exiting from the first circulation port 310; the flow of coolant entering the first circulation port 310 and exiting from the third circulation port 330; the flow of coolant entering the third circulation port 330 and exiting from the first circulation port 310; the flow of coolant entering the second circulation port 320 and exiting from the fourth circulation port 340; the flow of coolant entering the fourth circulation port 340 and exiting from the second circulation port 320; the flow of coolant entering the third circulation port 330 and exiting from the fourth circulation port 340; and the flow of coolant entering the fourth circulation port 340 and exiting from the third circulation port 330. These coolant circulation flows enable the coolant to exchange heat with the refrigerant as it circulates within the heat exchanger 100.

Here, the second and third circulation ports 320 and 330 are installed facing each other, and the first and fourth circulation ports 310 and 340 are installed facing each other, creating bypass paths for coolant flow. This enables the formation of bypass flow paths where coolant entering the second circulation port 320 exits through the third circulation port 330 or coolant entering the third circulation port 330 exits through the second circulation port 320. This also enables the formation of bypass flow paths where coolant entering the first circulation port 310 exits through the fourth circulation port 340 or coolant entering the fourth circulation port 340 exits through the first circulation port 310. This allows for coolant to pass through the heat exchanger 100 with minimal resistance.

As described, the present disclosure allows for heat exchange between coolant and refrigerant or for bypass of heat exchange with refrigerant, depending on the circulation port 300 through which the coolant flows among the plurality of circulation ports 300 for coolant circulation within the heat exchanger 100.

The heat exchanger apparatus 30 according to the present disclosure may be applied to construct a heat management system.

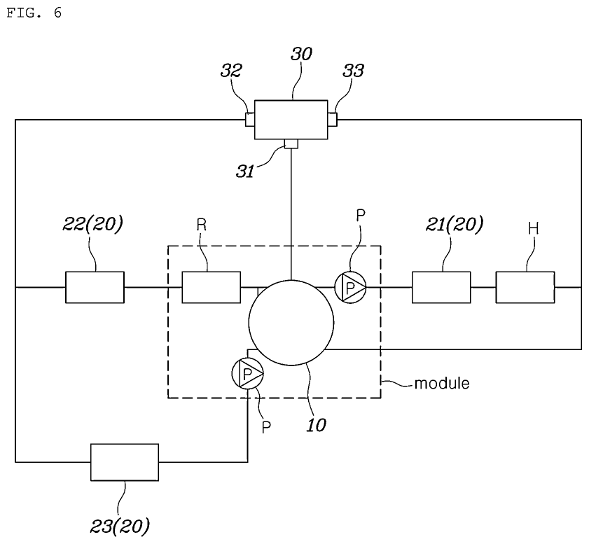

In detail, as shown in FIG. 6, in a heat management system, coolant is selectively circulated to a plurality of heat management components 20 through a coolant circulation line controlled by a multi-valve 10. In such a system, a heat exchanger apparatus 30 is provided in the coolant circulation line, connected to the multi-valve 10 and the different heat management components 20, to regulate the temperature of the coolant.

The heat management components 20 may include a battery 21, a radiator 22, and power electronics (PE) 23. The radiator 22 may be configured to exchange heat with the air to regulate the temperature of the cooling medium.

This allows for the branching of a plurality of coolant lines from the cooling medium circulation line, centered around the multi-valve 10. This enables control of the coolant flow direction through the opening and closing of the multi-valve 10.

The multi-valve 10 may be integrated with a reservoir R and coolant pumps P as a single module. Additionally, a water heating heater H is provided in the coolant line passing through the battery 21. These components, including the multi-valve 10, may be operated under the control of a controller.

In particular, the heat exchanger apparatus 30 is composed of heat exchange plates that allow for heat exchange between a cooling medium and another heat exchange medium. The heat exchanger apparatus 30 is equipped with a plurality of circulation ports 300 for cooling medium circulation. Some of the plurality of circulation ports 300 are arranged in a facing direction on the heat exchange plates, forming bypass paths. The cooling medium may be a coolant and the heat exchange medium may be a refrigerant.

In this way, the heat exchanger apparatus 30 may allow the coolant to circulate and exchange heat with the heat exchange medium within the heat exchanger 100, or bypass the heat exchange with minimal resistance, depending on the coolant circulation direction via the multi-valve 10.

In detail, the heat exchanger apparatus 30 may include a first circulation path 31 connected to the multi-valve 10, a second circulation path 32 connected to the radiator 22 or the PE 23, and a third circulation path 33 connected to the battery 21 or the multi-valve 10.

Here, the heat exchanger apparatus 30 may be configured such that the second circulation path 32 and the third circulation path 33 form a bypass path.

This allows each circulation path to serve as a route for the coolant to enter or exit. By controlling the multi-valve 10, various heat management modes can be implemented.

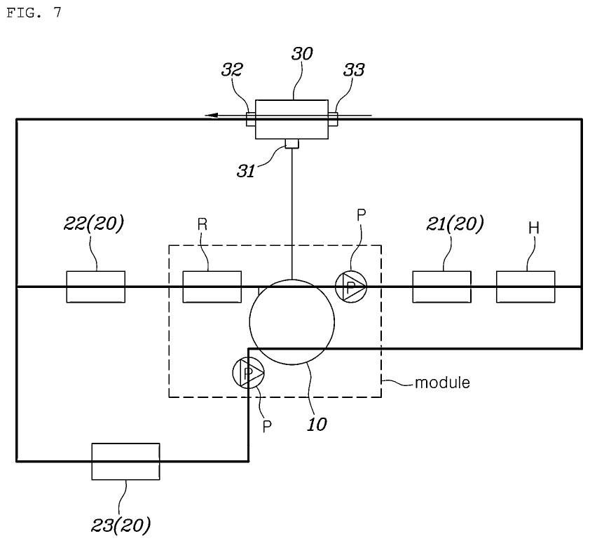

For example, as illustrated in FIG. 7, when the coolant, which is the cooling medium, cools the battery 21 and the PE 23, the multi-valve 10 may close the first circulation path 31 to form a circulation flow. This allows the coolant to enter the heat exchanger apparatus 30 through the third circulation path 33 and be discharged through the second circulation path 32.

Consequently, the coolant that has passed through the radiator 22 may circulate back after cooling the battery 21 and the PE 23, dissipating heat. In the case of the heat exchanger apparatus 30, the coolant may be bypassed.

In other words, when cooling the battery 21 and the PE 23

using the radiator 22, heat exchange of the coolant within the heat exchanger apparatus 30 is prevented. Accordingly, the multi-valve 10 may be closed on the side of the first circulation path 31, blocking the coolant circulation, allowing the coolant passed through the radiator 22 to circulate through the battery 21 and the PE 23 for cooling.

Particularly, after entering the third circulation path 33 of the heat exchanger apparatus 30, the coolant may bypass through the second circulation path 32, avoiding heat exchange with the heat exchange medium. Thus, the coolant temperature is maintained while passing through the heat exchanger apparatus 30.

This allows the mode of cooling the battery 21 and the PE 23 using the radiator 22 through the coolant circulation to be implemented.

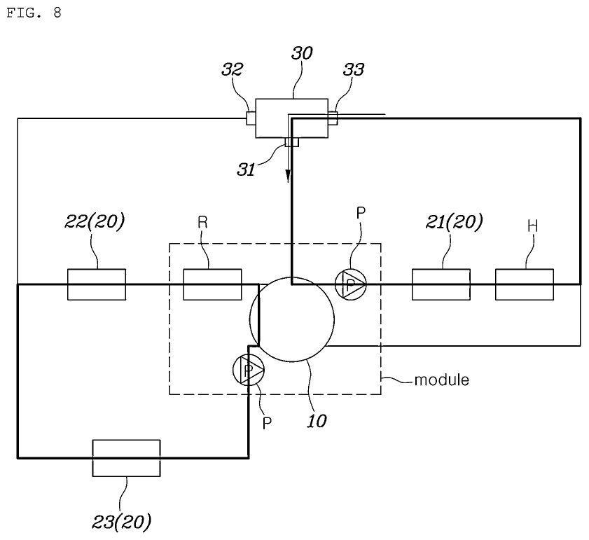

As shown in FIG. 8, in the case of cooling the battery 21 using the heat exchanger apparatus 30 and cooling the PE 23 through the radiator 22, the multi-valve 10 may open the first circulation path 31. This allows the coolant to enter the heat exchanger apparatus 30 through the third circulation path 33 and then be discharged through the first circulation path 31, forming a circulation flow of the coolant.

Consequently, the coolant that has passed through the battery 21 may circulate within the heat exchanger apparatus 30.

In other words, when cooling the battery 21 using the heat exchanger apparatus 30, heat exchange occurs between the coolant, which is the cooling medium, and the refrigerant, which is the heat exchange medium circulating for air conditioning purposes within the heat exchanger apparatus 30. To facilitate the heat exchange, the multi-valve 10 opens the first circulation path 31 to allow the circulation of the coolant, enabling the coolant that has cooled the battery 21 to undergo heat exchange with the refrigerant within the heat exchanger 100. In this process, the heat exchanger apparatus 30 may also manage the temperature of the refrigerant through heat exchange with the coolant that has cooled the battery 21, which may be utilized by the heat pump.

In the case of the PE 23, it may be configured to allow the coolant that has passed through the radiator 22 to circulate.

This configuration allows for implementing a mode in which the battery 21 is cooled via the heat exchanger apparatus 30, while the PE 23 is optionally cooled via the radiator 22.

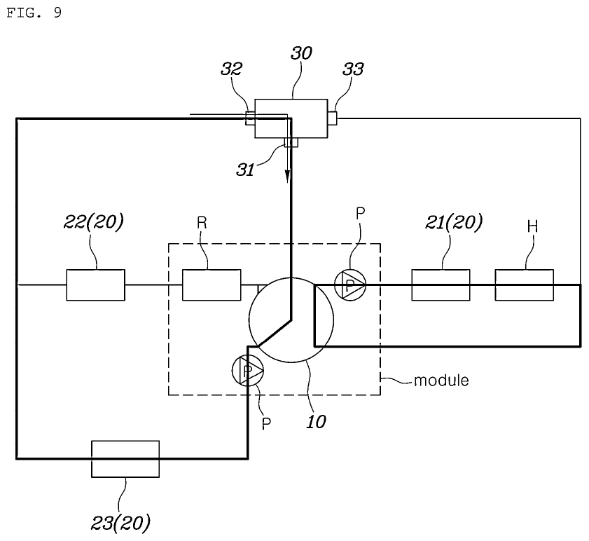

As shown in FIG. 9, in the case of cooling the PE 23 using the heat exchanger apparatus 30, the multi-valve 10 may open the first circulation path 31 to form a circulation flow. This allows the coolant to enter the second circulation path 32 of the heat exchanger apparatus 30 and then be discharged through the first circulation path 31.

As a result, the coolant that has passed through the PE 23 may circulate through the heat exchanger apparatus 30 via the multi-valve 10.

In other words, when cooling the PE 23 with the heat exchanger apparatus 30, heat exchange occurs between the coolant and the heat exchange medium within the heat exchanger apparatus 30. To achieve this, the multi-valve 10 is opened on the side of the first circulation path 31 to allow the coolant to circulate, while closed on the side of the radiator 22, enabling the coolant that has cooled the PE 23 to undergo heat exchange with the heat exchange medium within the heat exchanger 100, effectively managing the temperature of the coolant. In this case, the heat exchanger apparatus 30 may also manage the temperature of the heat exchange medium through heat exchange with the coolant that has cooled the PE 23, which may be utilized by the heat pump.

Here, when it is necessary to increase the temperature of the battery 21, the cooling medium may be heated by activating the water heater H, thereby raising the temperature of the battery 21.

As a result, the heat exchanger apparatus 30 may be utilized for cooling the PE 23 and implementing heat pump functionality.

The heat exchanger apparatus 30 and the heat management system using the same, structured as described above, facilitate temperature management of each cooling medium through heat exchange between the refrigerant and the coolant. The apparatus 30 and system also diversify the flow direction of the coolant by providing a bypass circulation path through which the coolant bypasses the heat exchange with the refrigerant in addition to the circulation path through which the coolant exchanges heat with the refrigerant. As a result, the manifold is eliminated for the bypass path through which the coolant bypass in the heat exchanger 100. This reduces the number of components, material costs, weight, and package size of the cooling circuit.

Although aspects of the present disclosure have been illustrated and described in connection with specific embodiments, it should be understood by those of ordinary skill in the art that various modifications and changes can be made thereto without departing from the spirit of the disclosure or the scope of the appended claims.

What is claimed is:

1. A heat exchanger apparatus comprising:
a heat exchanger including a plurality of stacked heat exchange plates equipped with a guide member forming a flow path for flow of refrigerant or coolant;
a refrigerant inlet and a refrigerant outlet connected to the heat exchanger to allow the refrigerant to flow and circulate through some of the plurality of heat exchange plates; and
a plurality of circulation ports connected to the heat exchanger to allow the coolant to flow and circulate through some of the plurality of heat exchange plates,
wherein some of the plurality of circulation ports are installed to face each other in the heat exchanger to form a bypass path.

2. The heat exchanger apparatus of claim 1, wherein the heat exchanger comprises a heat exchange plate for the refrigerant and a heat exchange plate for the coolant, the heat exchange plate for the refrigerant being communicably connected with the refrigerant inlet and the refrigerant outlet, and the heat exchange plate for the coolant being communicably connected with the plurality of circulation ports.

3. The heat exchanger apparatus of claim 1, wherein the refrigerant inlet and refrigerant outlet are positioned on both sides of the guide member, and wherein some circulation ports are positioned on both sides of the guide member on the opposite side of the refrigerant inlet and refrigerant outlet.

4. The heat exchanger apparatus of claim 1, wherein the plurality of circulation ports comprises a first circulation port, a second circulation port, and a third circulation port, wherein the first and second circulation ports are installed on one side of the heat exchanger, and wherein the third circulation port is installed on the opposite side of the heat exchanger in a direction facing the first circulation port or the second circulation port to communicate with each other.

5. The heat exchanger apparatus of claim 1, wherein the plurality of circulation ports comprises a first circulation port, a second circulation port, a third circulation port, and a fourth circulation port, wherein the first and second circulation ports are installed on one side of the heat exchanger, wherein the third circulation port is installed on the opposite side of the heat exchanger in a direction facing the first circulation port, and wherein the fourth circulation port is installed on the opposite side of the heat exchanger in a direction facing the second circulation port.

6. A heat management system including a multi-valve configured to circulate refrigerant selectively through a plurality of heat management components in a cooling medium circulation line, the heat management system comprising:
a heat exchanger apparatus connected to the multi-valve; and
other heat management components in the cooling medium circulation line to adjust a temperature of the cooling medium,
wherein the heat exchanger apparatus includes
heat exchange plates for heat exchange between the cooling medium and heat exchange medium, and
a plurality of circulation ports for circulation of the cooling medium, some of the circulation ports being arranged in a direction facing each other to form a bypass path in the heat exchanger apparatus.

7. The heat management system of claim 6, wherein the heat management components comprise a battery, a radiator, and power electronics (PE), and wherein the heat exchanger apparatus includes a first circulation path connected to the multi-valve, a second circulation path connected to the radiator or the PE, and a third circulation path connected to the battery or the multi-valve.

8. The heat management system of claim 7, wherein the heat exchanger apparatus is configured to have a bypass path formed by the second and third circulation paths.

9. The heat management system of claim 8, wherein the multi-valve is configured to close the first circulation path when cooling the battery or PE using the radiator to form a circulation flow allowing the cooling medium to enter the heat exchanger apparatus through the third circulation path and be discharged through the second circulation path.

10. The heat management system of claim 9, wherein the multi-valve is configured to circulate the cooling medium passed through the battery to the radiator through the PE and heat exchanger apparatus when cooling the battery or PE using the radiator.

11. The heat management system of claim 8, wherein the multi-valve is configured to open the first circulation path when cooling the battery using the heat exchanger apparatus to form a circulation flow allowing the cooling medium passed through the third circulation path of the heat exchanger apparatus to be discharged through the first circulation path.

12. The heat management system of claim 11, wherein the multi-valve is configured to circulate the cooling medium passed through the battery to the heat exchanger apparatus when cooling the battery using the heat exchanger apparatus.

13. The heat management system of claim 8, wherein the multi-value is configured to open the first circulation path when implementing heat pump functionality using the heat exchanger apparatus to form a circulation flow allowing the cooling medium passed through the second circulation path of the heat exchanger apparatus to be discharged through the first circulation path.

14. The heat management system of claim 13, wherein the multi-valve is configured to circulate the cooling medium passed through the PE to the heat exchanger apparatus when implementing the heat pump functionality using the heat exchanger apparatus.
